(19) United States
(12) Patent Application Publication
(10) Pub. No.: US 2023/0178368 A1
(43) Pub. Date: Jun. 8, 2023

(54) COMPOSITE SUBSTRATE, METHOD FOR PRODUCING COMPOSITE SUBSTRATE, SEMICONDUCTOR DEVICE, AND METHOD FOR PRODUCING SEMICONDUCTOR DEVICE

(71) Applicant: Mitsubishi Electric Corporation, Tokyo (JP)

(72) Inventor: Hiroyuki KINOSHITA, Tokyo (JP)

(73) Assignee: Mitsubishi Electric Corporation, Tokyo (JP)

(21) Appl. No.: 17/995,463

(22) PCT Filed: Jun. 1, 2020
(86) PCT No.: PCT/JP2020/021534

§ 371 Date: Oct. 4, 2022

(51) Int. Cl. H01L 21/02; H01L 29/66; H01L 29/778

(52) U.S. Cl. CPC H01L 21/0245; H01L 21/02002; H01L 29/66462; H01L 29/7786; H01L 21/02488; H01L 21/02378; H01L 21/02502; H01L 21/0254; H01L 21/02658; H01L 29/2003

(57) ABSTRACT

A composite substrate of the present disclosure is composed of two parts: a SiC substrate; and a Si-containing thermal-sprayed layer made of a material obtained by melting Si or a Si alloy through thermal spraying. The Si-containing thermal-sprayed layer serves as a support substrate for supporting the SiC substrate so as to keep the mechanical strength thereof, and is provided at one surface of the SiC substrate on the side opposite to a surface where a nitride semiconductor layer composed of layers made of nitride semiconductors such as an AlN buffer layer, a GaN buffer layer, and an AlGaN Schottky layer is formed through epitaxial growth.

### TECHNICAL FIELD

The present disclosure relates to a composite substrate, a method for producing a composite substrate, a semiconductor device, and a method for producing a semiconductor device.

### BACKGROUND ART

A nitride semiconductor such as gallium nitride (GaN) has a larger band gap and a higher saturation electron velocity than silicon (Si) or gallium arsenide (GaAs), and therefore is suitable for a constituent material of an electronic device that operates with high output and at high speed.

One representative example of such electronic devices is a high-electron-mobility transistor (gallium nitride high electron mobility transistor: GaN-HEMT) using a nitride semiconductor as a constituent material, and this has been studied, developed, and further, put into practical use.

As a substrate material of the GaN-HEMT, a silicon carbide (SiC) substrate, a silicon (Si) substrate, a sapphire substrate, or the like is used.

In the GaN-HEMT, manufacturing is performed by epitaxially growing a nitride semiconductor layer which will be an operation layer on the above substrate using metal-organic vapor phase epitaxy (MOVPE), for example.

The SiC substrate is higher in heat dissipation property than the Si substrate or the sapphire substrate, and therefore is suitable for a substrate of the GaN-HEMT. However, as compared to the Si substrate which is often used as a substrate for widespread electronic devices such as a large scale integration (LSI) circuit and a flash memory, the SiC substrate requires a relatively high technology level in crystal growth technology and wafer processing technology, and mass production thereof is more difficult. Therefore, the SiC substrate is more expensive than the Si substrate. Thus, there is a problem that the production cost for an electronic device using the SiC substrate also increases.

For reducing the production cost for the SiC substrate, the following composite substrate manufacturing technology is disclosed: single-crystal SiC having a high quality is used for only a device formation layer part, the single-crystal SiC is fixed to a support substrate made of a material having a mechanical strength, heat resistance, and cleanliness that can withstand a device manufacturing process, by using a bonding technology not accompanied with formation of an oxide film at the bonding interface, thereby producing a composite substrate that achieves both of low cost owing to the support substrate and a high quality owing to the SiC substrate. One example of a material for the support substrate is polycrystalline SiC (see, for example, Patent Documents 1 and 2).

### CITATION LIST

### Patent Document

Patent Document 1: Japanese Laid-Open Patent Publication No. 2015-15401

Patent Document 2: Japanese Laid-Open Patent Publication No. 2018-14372

### SUMMARY OF THE INVENTION

### Problems to be Solved by the Invention

In manufacturing a composite substrate using a technology for bonding between different types of substrates for the purpose of production cost reduction, in order to prevent formation of a non-bonded part (called void) between bonding surfaces of the different types of substrates, extremely favorably finished bonding surfaces and an extremely clean work environment are both essential. Therefore, extremely strict process management and environment management are necessary, and reduction in the production yield of the composite substrate is inevitable, leading to increase in production cost.

In manufacturing the composite substrate using bonding between different types of substrates, a substrate as a support layer, i.e., a support substrate needs to be used, and bonding surfaces of both of the support layer and each semiconductor layer as a function part need to be polished to be flat at a high level.

In a case of using a polycrystalline substrate made of SiC as the support substrate for the SiC substrate, in terms of materials, both materials are the same SiC and therefore their mechanical properties such as thermal expansion can be easily matched. However, the polycrystalline SiC substrate which is higher in cost than a general Si substrate is used as the support substrate, and further, it is necessary to manage warp, surface roughness, and the like with severe specifications, thus inevitably leading to increase in production cost.

In a case of using the SiC substrate as a substrate for the GaN-HEMT, a necessary thickness of the SiC substrate for the completed GaN-HEMT is several tens to 100 μm at most, whereas a necessary thickness of the SiC substrate when a nitride semiconductor layer is formed through epitaxial growth is as great as 0.5 mm in a case of 4-inch diameter. Therefore, in a production process after the epitaxial growth, it is necessary to grind unnecessary SiC for the electronic device by 0.4 mm or more from the back surface side of the SiC substrate. However, since SiC is a hard-to-work material, time and cost are required for the grinding and removal, leading to increase in production cost.

The present disclosure has been made to solve the above problem, and an object of the present disclosure is to provide a composite substrate and a method for producing the composite substrate which are low in production cost and high in quality, and further, provide a semiconductor device using the composite substrate and a method for producing the semiconductor device.

### Solution to the Problems

A composite substrate according to the present disclosure includes: a SiC substrate; and a Si-containing thermal-sprayed layer which is provided at one surface of the SiC substrate so as to support the SiC substrate and is made of a material obtained by melting Si or a Si alloy.

### Effect of the Invention

The composite substrate according to the present disclosure is composed of the SiC substrate and the Si-containing thermal-sprayed layer. Therefore, as compared to the conventional composite substrate, the composite substrate according to the present disclosure has such a structure that does not need a grinding step of grinding the SiC substrate into a thinned plate or a step of bonding the SiC substrate and the support substrate, and thus an effect of obtaining a composite substrate at low cost and with high quality is provided.

In the method for producing the semiconductor device according to the present disclosure, the composite substrate composed of the SiC substrate and the Si-containing thermal-sprayed layer is used as a substrate, thus providing an effect that, even when a nitride semiconductor layer is epitaxially grown on the composite substrate, occurrence of separation between the SiC substrate and the Si-containing thermal-sprayed layer is suppressed and electric property variation of the semiconductor device in the wafer surface is suppressed.

### BRIEF DESCRIPTION OF THE DRAWINGS

FIG. 1 is a flowchart showing a method for producing a composite substrate according to embodiment 1.

FIG. 2 is a sectional view of the composite substrate composed of a SiC substrate and a Si-containing thermal-sprayed layer according to embodiment 1.

FIG. 3 is a sectional view of the composite substrate composed of the SiC substrate and the Si-containing thermal-sprayed layer according to embodiment 1, and shows, in particular, cavities in the Si-containing thermal-sprayed layer.

FIG. 4 is a sectional view of the composite substrate composed of the SiC substrate and the Si-containing thermal-sprayed layer according to embodiment 1.

FIG. 5 is a sectional view of a GaN-HEMT with the Si-containing thermal-sprayed layer removed.

FIG. 6 is a sectional view of a GaN-HEMT with the Si-containing thermal-sprayed layer remaining.

FIG. 7 shows the relationship between sheet resistance variation of the GaN-HEMT and the thickness of the Si-containing thermal-sprayed layer.

FIG. 8 shows the relationship between the warp amount of the composite substrate at a high temperature and the thickness of the SiC substrate, using the thickness of the Si-containing thermal-sprayed layer as a parameter.

FIG. 9 is a sectional view of a composite substrate having a Si-containing thermal-sprayed layer in which ceramic is dispersed, according to embodiment 2.

FIG. 10 is a sectional view of a composite substrate having a Si-containing thermal-sprayed layer doped with impurities according to embodiment 3.

FIG. 11 is a sectional view of a composite substrate having an intermediate layer between a SiC substrate and a Si-containing thermal-sprayed layer according to embodiment 4.

FIG. 12 is a flowchart showing a method for producing a GaN-HEMT according to embodiment 5.

### DESCRIPTION OF EMBODIMENTS

### Embodiment 1

In order to solve the above-described technical problem, the inventor of the present application has found out a composite substrate structure in which a Si-containing thermal-sprayed layer formed by spraying Si is used as a support substrate for a SiC substrate. This is because, in such a support substrate made from a Si-containing thermal-sprayed layer formed by spraying Si, void defect or the like is originally not present, a support substrate need not be prepared separately, and in addition, high-level polishing for bonding surfaces is not needed and therefore a work environment with high cleanliness is not needed.

Further, the inventor of the present application has found out, under the condition for suppressing great warp of the composite substrate at a high temperature when a nitride semiconductor layer is epitaxially grown, which is needed for manufacturing a GaN-HEMT on the SiC substrate side of the composite substrate having the Si-containing thermal-sprayed layer formed by spraying Si, a method for suppressing electric property variation of the nitride semiconductor layer in the wafer surface and a method for preventing separation between the SiC substrate and the Si-containing thermal-sprayed layer.

Hereinafter, the structure of the composite substrate and the method for producing the composite substrate according to the present disclosure will be described.

In the following description, for simplification, a composite substrate having a 4-inch diameter is used as a representative example, to describe a working method for the composite substrate, a setting condition, and the like. However, as a matter of course, the same concept can be applied also to a substrate having a diameter other than 4 inches, though the condition of the thickness of the support substrate is different.

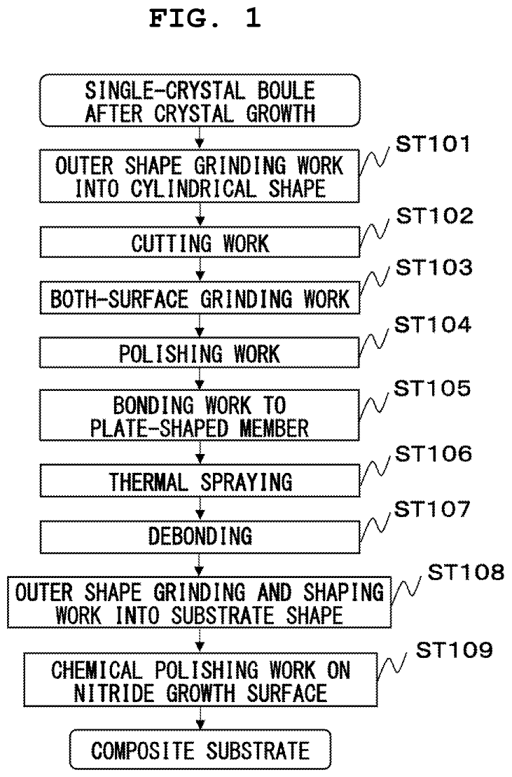

The method for producing the composite substrate according to embodiment 1 will be described with reference to a flowchart in FIG. 1.

First, an outer shape grinding work is performed to make the outer shape of a SiC single-crystal boule after crystal growth into a cylindrical shape (step ST101).

The cylindrical-shaped SiC single crystal is cut into a wafer-shaped SiC substrate 1 with the thickness controlled to be 0.12 to 0.25 mm, using a wire saw or the like (step ST102).

The cut wafer-shaped SiC substrate 1 is ground on both surface sides to suppress thickness variation (step ST103).

The SiC substrate 1 is manufactured by polishing one or both surfaces thereof so that the thickness of the SiC substrate 1 falls within a range of 0.02 mm to 0.1 mm and thickness variation becomes 0.01 mm or less (step ST104).

Considering thickness variation of the SiC substrate 1, the thickness of the SiC substrate 1 after the polishing work falls into a range of 0.01 mm to 0.10 mm.

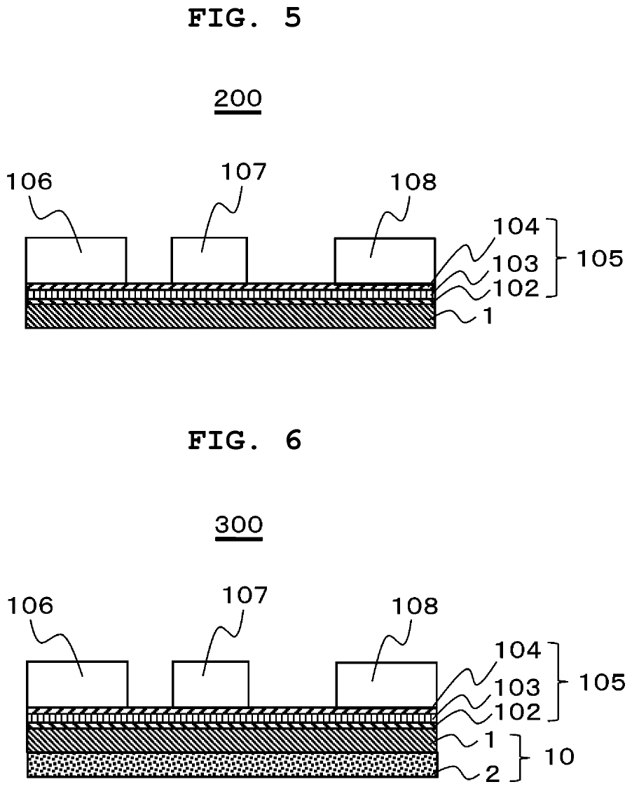

When a nitride semiconductor layer 105 (shown in FIG. 5 below) is epitaxially grown on the SiC substrate 1 having a thickness of 0.10 mm or less by MOVPE, the SiC substrate 1 greatly bows or cracks due to stress arising at the interface between the SiC substrate 1 and the nitride semiconductor layer 105 and the difference between their thermal expansion coefficients. In order to prevent such failure, a Si-containing thermal-sprayed layer 2 serving as a support substrate for the SiC substrate 1 is formed by the following production method. Hereinafter, the SiC substrate 1 with the Si-containing thermal-sprayed layer 2 formed thereon is referred to as a composite substrate 10.

A surface on a side where the nitride semiconductor layer 105 is to be epitaxially grown on the SiC substrate 1 polished to have a thickness of 0.1 mm or less is bonded to a plate-shaped member finished to have a flatness of 0.01 mm or less, via low-melting-point glass, low-melting-point metal, or the like (step ST105). One example of the plate-shaped member is a ceramic plate-shaped member made of alumina ceramic or the like.

By bonding the SiC substrate 1 to the plate-shaped member having a favorable flatness, warp of the thinned-plate SiC substrate 1 after the bonding work step is greatly improved, irrespective of the shape of the SiC substrate 1.

In addition, the thickness of the SiC substrate 1, which is 0.1 mm or less, is much smaller than a conventional general SiC substrate thickness (0.5 mm), and the SiC substrate 1 need not be further ground. Therefore, it is not necessary to perform a grinding step of grinding a SiC substrate by 0.4 mm or more, which is needed for a conventional general SiC substrate. Thus, time and cost required for the grinding step can be eliminated, so that the production cost for the substrate and therefore the production cost for the electronic device using the SiC substrate can be reduced.

Next, of the surfaces of the SiC substrate 1, the surface that is not covered by the ceramic plate-shaped member is sprayed with Si (step ST106). One example of a method for spraying Si is low pressure plasma spraying. In the low pressure plasma spraying, Si is sprayed inside a decompression chamber to which an inert gas such as argon (Ar) or nitrogen (molecular nitrogen: N₂) is supplied as an atmospheric gas.

Through the Si thermal spraying step, the Si-containing thermal-sprayed layer 2 is formed on one surface side of the SiC substrate 1. As described above, the Si-containing thermal-sprayed layer 2 serves as a support substrate for supporting the thinned-plate SiC substrate 1.

From the standpoint of effectively supporting the SiC substrate 1, it is desirable that the thickness of the Si-containing thermal-sprayed layer 2 is 0.5 mm or more. In addition, in order to prevent temperature increase in the SiC substrate 1 at the time of the Si thermal spraying, it is preferable that Si is sprayed to the SiC substrate 1 intermittently at two or three divisional times, in forming the Si-containing thermal-sprayed layer 2.

After the Si-containing thermal-sprayed layer 2 is formed, the ceramic plate-shaped member is debonded from the composite substrate 10 composed of the SiC substrate 1 and the Si-containing thermal-sprayed layer 2, by etching or heating (step ST107).

In a case of epitaxially growing the nitride semiconductor layer 105 on the composite substrate 10 after the debonding step, the outer shape of the composite substrate 10 is subjected to an outer shape grinding and shaping work so as to reduce outer shape variation of the Si-containing thermal-sprayed layer 2 (step ST108). In a case of manufacturing a GaN-HEMT using the composite substrate 10 after the debonding step, the thickness of the Si-containing thermal-sprayed layer 2 needs to be at least 0.5 mm or more.

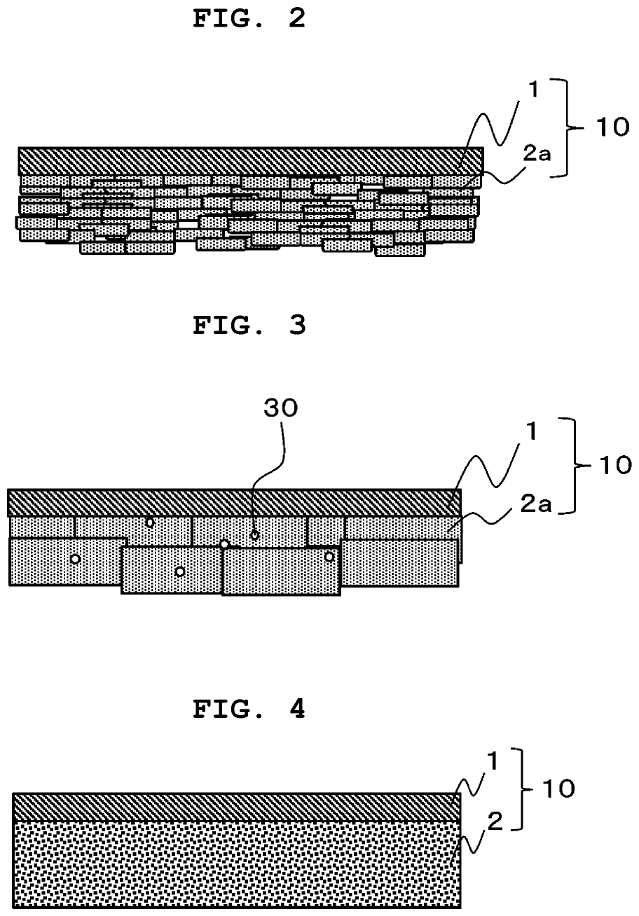

Epitaxial growth of the nitride semiconductor layer 105 may be performed after a chemical polishing work is performed subsequent to the debonding work. However, as shown in a schematic sectional view in FIG. 2, a Si-containing thermal-sprayed layer 2a after the Si thermal spraying step has a coarse structure including random grain boundaries or hollows. Therefore, heat treatment is performed for the purpose of stabilizing electric properties and mechanical properties, degassing, and surface oxidization. One example of the heat treatment condition is that heat treatment is performed for about one hour at a heat treatment temperature of 1400 degrees in an inert gas atmosphere containing a slight amount of oxygen at the atmospheric pressure. FIG. 3 shows a sectional view of the composite substrate 10 after the heat treatment. In FIG. 3, a characteristic structure of the Si-containing thermal-sprayed layer 2 after the heat treatment, in particular, cavities 30 in the Si-containing thermal-sprayed layer 2, are drawn so as to be emphasized.

In the case where the heat treatment is performed, the same outer shape grinding and shaping work as in step ST108 is performed after the heat treatment step.

Irrespective of whether or not the heat treatment is performed, after the outer shape grinding and shaping work is performed, the surface on the side where the nitride semiconductor layer 105 is to be epitaxially grown is polished by chemical polishing and cleaned (step ST109), whereby the composite substrate 10 is completed as shown in a sectional view in FIG. 4.

Thus, the structure of the composite substrate 10 and the production method therefor according to embodiment 1 have been described.

As shown in the sectional view in FIG. 2, the Si-containing thermal-sprayed layer 2a after the Si thermal spraying is formed such that melted Si grains or Si-containing grains are overlaid. Also in the Si-containing thermal-sprayed layer 2 after the heat treatment shown in a sectional view in FIG. 4, grain boundaries appear remarkably. Since the Si-containing thermal-sprayed layer 2 has such features, it is possible to easily confirm that the Si-containing thermal-sprayed layer 2 is a layer formed through thermal spraying, by observing a cross-section using a microscope such as a scanning electron microscope (SEM).

The condition of the thickness of the SiC substrate 1 described above has the following constraints. Hereinafter, a case where the diameter of the SiC substrate 1 is 4 inches will be described. It is noted that, also in a case where the diameter of the SiC substrate 1 is other than 4 inches, the ratio of the thickness of the Si-containing thermal-sprayed layer 2 to that of the SiC substrate 1 is set in a certain range in accordance with the substrate diameter.

First, the thickness of the SiC substrate 1 is, at maximum, 0.1 mm or less due to constraints in terms of the structure of the electronic device to be produced using the SiC substrate 1, and therefore the maximum thickness of the SiC substrate 1 is set at 0.1 mm.

To further describe the constraints in terms of the structure of the electronic device, the thickness of the SiC substrate 1 depends on trade-off between the cost and the advantage that favorable heat diffusion performance of SiC can be effectively exerted in the completed electronic device. This is because the heat diffusion performance is less effective if the thickness of the SiC substrate 1 is greater than 0.1 mm.

In addition to the above constraints, in particular, in a case of providing via-holes to the electronic device, if the thickness of the SiC substrate 1 is greater than 0.1 mm, a via work for the SiC substrate 1 requires a long time, so that mass productivity is significantly reduced.

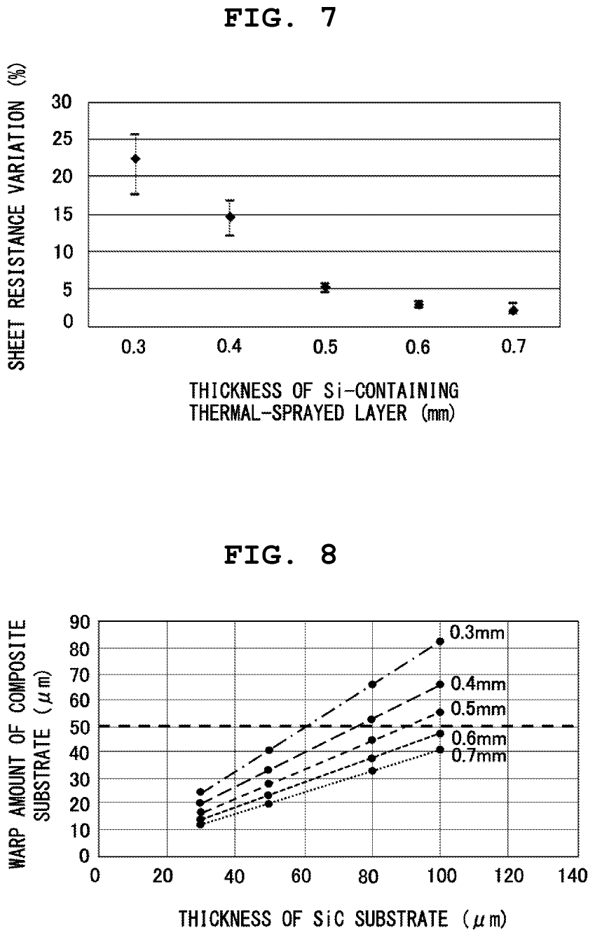

On the above composite substrate 10, the nitride semiconductor layer 105 composed of an AlN buffer layer 102, a GaN buffer layer 103, and an AlGaN Schottky layer 104 is epitaxially grown to form a GaN-HEMT 200 shown in a sectional view in FIG. 5 or a GaN-HEMT 300 shown in a sectional view in FIG. 6. In this case, if the thickness of the Si-containing thermal-sprayed layer 2 is 0.4 mm or less, sheet resistance variation of the GaN-HEMT 300 in the wafer surface reaches 15% or higher as is found from a graph showing the relationship between sheet resistance variation of the GaN-HEMT 300 and the thickness of the Si-containing thermal-sprayed layer 2 in FIG. 7.

Here, FIG. 5 is a sectional view of the GaN-HEMT with the Si-containing thermal-sprayed layer 2 removed, and FIG. 6 is a sectional view of the GaN-HEMT 300 with the Si-containing thermal-sprayed layer 2 remaining.

It has been found out that a phenomenon in which sheet resistance variation in the wafer surface becomes great is caused by the following reason: according to analysis on the thickness of the nitride semiconductor layer 105, the thicknesses of the GaN buffer layer 103 and the AlGaN Schottky layer 104 greatly vary in the wafer surface, and therefore the carrier concentrations in these layers vary, so that the carrier concentration variation is directly reflected in the sheet resistance.

It is inferred that a phenomenon in which the thickness of the nitride semiconductor layer 105 greatly varies even though the shape of the SiC substrate 1 after the epitaxial growth is not greatly warped, is due to warp of the SiC substrate 1 at a high temperature during the epitaxial growth, instead of the shape of the SiC substrate 1 at room temperature. From thermal characteristics of the SiC substrate 1 and the Si-containing thermal-sprayed layer 2 measured strictly, regarding warp of the composite substrate 10 when the nitride semiconductor layer 105 is epitaxially grown at a growth temperature of 1200 degrees, it is figured out through calculation that the warp amount of the composite substrate 10 at the high temperature and the thickness of the SiC substrate 1 are in a relationship as shown in FIG. 8, using the thickness of the Si-containing thermal-sprayed layer 2 as a parameter.

In a conventional substrate formed by a SiC substrate alone, sheet resistance variation is 3% or less in a range where the warp value of the composite substrate 10 is not greater than approximately 0.05 mm (50 μm) at room temperature. Therefore, with the warp value of 0.05 mm (50 μm) of the composite substrate 10 set as a standard, in FIG. 8, a thickness of 0.5 mm of the Si-containing thermal-sprayed layer 2 is used as a reference and a total of five levels of thicknesses of the Si-containing thermal-sprayed layer 2 are set around the thickness of 0.5 mm, i.e., between 0.3 mm and 0.7 mm. Then, a result of evaluating sheet resistance variation when the nitride semiconductor layer 105 is epitaxially grown is shown in FIG. 7 described above.

From FIG. 7, it is found out that, if the thickness of the Si-containing thermal-sprayed layer 2 is less than 0.5 mm, sheet resistance variation tends to sharply increase beyond 5%, thus causing a problem in practical use of the GaN-HEMT 300.

On the other hand, if the thickness of the SiC substrate 1 is decreased, a calculated thickness of the Si-containing thermal-sprayed layer 2 needed for suppressing warp of the composite substrate 10 at a high temperature is also decreased. However, because of stress due to the nitride semiconductor layer 105, if the Si-containing thermal-sprayed layer 2 is thinned, warp of the composite substrate 10 at room temperature tends to increase, and there are no other advantages conceivable. Therefore, as the thickness of the Si-containing thermal-sprayed layer 2, values of 0.5 mm or less need not be considered.

Further, if the thickness of the SiC substrate 1 is increased beyond 0.1 mm (100 μm), a calculated thickness of the Si-containing thermal-sprayed layer 2 that is needed tends to increase. However, as described above, such a setting condition leads to cost increase for SiC and thus contradicts the object of the present disclosure. Therefore, in the present disclosure, the SiC substrate 1 having a thickness greater than 0.1 mm (100 μm) is excluded.

As described above, the composite substrate according to embodiment 1 is composed of the SiC substrate and the Si-containing thermal-sprayed layer. Therefore, as compared to the conventional composite substrate, the composite substrate according to embodiment 1 has such a structure that does not need a grinding step of grinding the SiC substrate into a thinned plate or a step of bonding the SiC substrate and the support substrate, and thus an effect of obtaining a composite substrate at low cost and with high quality is provided.

In addition, in a case of using the composite substrate according to embodiment 1 as a substrate for producing an electronic device, an excellent effect of reducing electric property variation of the electronic device in the wafer surface is provided.

In addition, in the method of producing the composite substrate according to embodiment 1, a grinding step of grinding the SiC substrate into a thinned plate or a step of bonding the SiC substrate and the support substrate is not needed, and thus an effect of enabling a composite substrate to be produced at low cost and with high quality is provided.

In particular, a support substrate worked and finished with severe specifications is not needed and bonding defect such as void defect does not occur. Also for this reason, the above effect of enabling a composite substrate to be produced at low cost and with high quality is provided.

### Embodiment 2

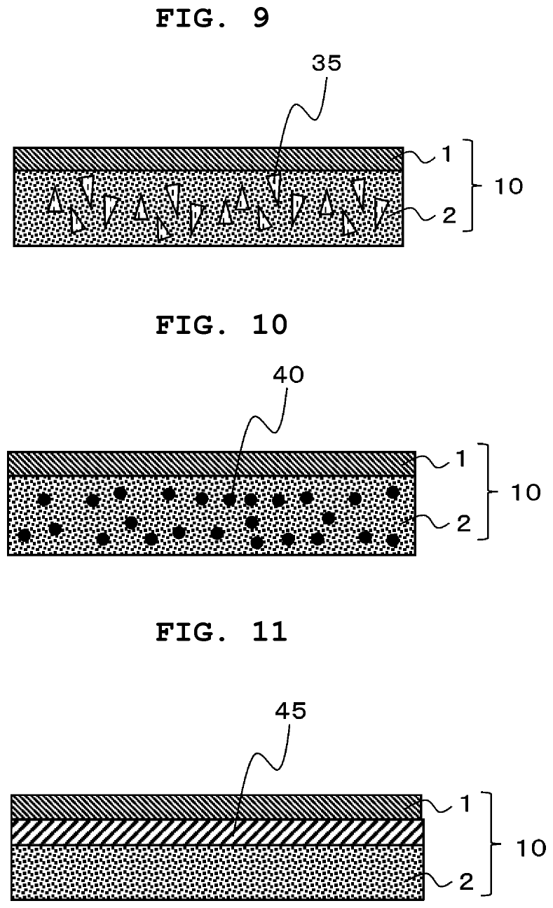

In a composite substrate 10 according to embodiment 2, as shown in a sectional view in FIG. 9, ceramic such as aluminum nitride (AlN), boron nitride (BN), and carbon (C) is mixed as a dispersion material 35 in the Si-containing thermal-sprayed layer 2. Regarding the crystal structure of BN, difference between a tetragonal crystal and a hexagonal crystal poses no problem for the dispersion material 35. Similarly, also regarding C, difference in crystal structures such as diamond, nanotube, and graphite poses no problem, and any of the crystal structures provides the same effect as the dispersion material 35.

If the dispersion material 35 made of ceramic is mixed in the Si-containing thermal-sprayed layer 2, thermal expansion difference between the SiC substrate 1 and the Si-containing thermal-sprayed layer 2 is reduced, thus providing an effect of suppressing warp of the composite substrate 10 at a high temperature when the nitride semiconductor layer 105 is epitaxially grown.

Further, in a case of producing a GaN-HEMT using the composite substrate 10 according to embodiment 2, an effect of improving the heat dissipation property of the GaN-HEMT is provided.

### Embodiment 3

In a composite substrate 10 according to embodiment 3, as shown in a sectional view of the composite substrate in FIG. 10, the Si-containing thermal-sprayed layer 2 is doped with impurities 40. A specific example of the impurities 40 is boron (B) or arsenic (As). However, the impurities 40 are not limited thereto.

The mechanical strength of the composite substrate 10 is improved by doping of the impurities 40, thus providing an effect of suppressing warp of the composite substrate 10 at a high temperature when the nitride semiconductor layer 105 is epitaxially grown.

### Embodiment 4

In a composite substrate according to embodiment 4, as shown in a sectional view in FIG. 11, a silicon oxide (SiOₓ) intermediate layer 45 serving as an intermediate layer is provided between the SiC substrate 1 and the Si-containing thermal-sprayed layer 2. The SiOₓ intermediate layer 45 is typically made of silicon dioxide (SiO₂). The SiOₓ intermediate layer 45 is formed by a film forming method such as oxidation or sputtering.

By providing the SiOₓ intermediate layer 45, stress due to thermal expansion difference between the SiC substrate 1 and the Si-containing thermal-sprayed layer 2 at a high temperature when the nitride semiconductor layer 105 is epitaxially grown, is relaxed, thus providing an effect of suppressing warp of the SiC substrate 1 at a high temperature. Preferably, such a thickness of the SiOₓ intermediate layer 45 as to provide an effect of substantially relaxing stress and suppressing warp is 2000 angstroms (200 nm) or more, according to calculation.

### Embodiment 5

A GaN-HEMT 300 according to embodiment 5 is manufactured by using the composite substrate 10 as a substrate and epitaxially growing the nitride semiconductor layer 105 on the composite substrate 10. In the composite substrate 10, the Si-containing thermal-sprayed layer 2 remains without being removed, as shown in the sectional view in FIG. 6.

Hereinafter, the structure of the GaN-HEMT 300 and the production method therefor according to embodiment 5 will be described.

FIG. 6 is a sectional view of the GaN-HEMT 300 according to embodiment 5. The GaN-HEMT 300 includes the composite substrate 10 having the structure disclosed in any one of embodiments 1 to 4. On the composite substrate 10, a semiconductor layer composed of a plurality of nitride semiconductors is formed. The formed semiconductor layer is referred to as the nitride semiconductor layer 105.

Specifically, the AlN buffer layer 102 is formed on the composite substrate 10, the GaN buffer layer 103 is formed on the AlN buffer layer 102, and the AlGaN Schottky layer 104 is formed on the GaN buffer layer 103. With the AlN buffer layer 102, the GaN buffer layer 103, and the AlGaN Schottky layer 104 formed in this order on the composite substrate 10, a heterojunction structure is formed.

On the AlGaN Schottky layer 104, a gate electrode 107, a source electrode 106, and a drain electrode 108 are formed. The source electrode 106 and the drain electrode 108 as ohmic electrodes are formed by forming metal films such as AlTi and Au in this order on the AlGaN Schottky layer 104.

The gate electrode 107 as a Schottky electrode is formed by forming metal films such as Pt and Au in this order on the AlGaN Schottky layer 104.

In the above GaN-HEMI 300, a two-dimensional electron gas is formed directly under the heterojunction interface between the AlGaN Schottky layer 104 and the GaN buffer layer 103. The two-dimensional electron gas serves as a carrier traveling layer. That is, when bias voltage is applied between the source electrode 106 and the drain electrode 108, electrons supplied from the AlGaN Schottky layer 104 to the GaN buffer layer 103 travel in the two-dimensional electron gas and move to the drain electrode 108. At this time, by controlling voltage applied to the gate electrode 107 so as to change the thickness of a depletion layer directly under the gate electrode 107, current flowing from the source electrode 106 to the drain electrode 108 is controlled.

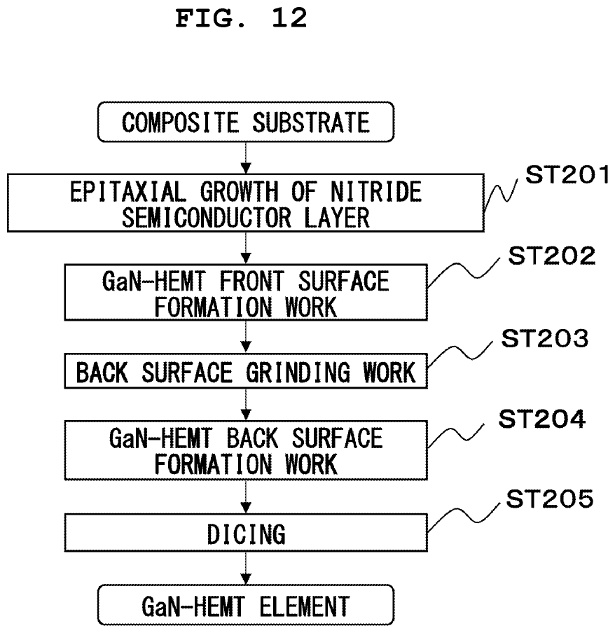

FIG. 12 is a flowchart showing a method for producing the GaN-HEMI 300 according to embodiment 5. Step ST201 is a crystal growth step of forming the nitride semiconductor layer 105 through epitaxial growth by MOVPE.

First, the AlN buffer layer 102 is epitaxially grown on the composite substrate 10. The thickness of the AlN buffer layer 102 is, for example, 30 nm.

Next, the GaN buffer layer 103 doped with carbon is epitaxially grown on the AlN buffer layer 102. The thickness of the GaN buffer layer 103 is, for example, 2 μm. By controlling the growth speed of the GaN buffer layer 103, the carbon addition concentration in the GaN buffer layer 103 is controlled. The conductivity type of the GaN buffer layer 103 is p-type.

Next, the AlGaN Schottky layer 104 is epitaxially grown. The thickness of the AlGaN Schottky layer 104 is, for example, 30 nm.

In step ST202, by an electron beam acceleration device, an electron beam is applied to the composite substrate 10 on which the nitride semiconductor layer 105 has been epitaxially grown in step ST201.

In the electron beam application step, an electron beam is applied from above the AlGaN Schottky layer 104, whereby electrons are applied to the AlGaN Schottky layer 104 and the GaN buffer layer 103.

After the electron beam application step, an electrode formation step is performed as described below.

By patterning using photolithography, a mask made of a SiO₂ film is formed on the AlGaN Schottky layer 104. Thereafter, in areas of the mask where the source electrode 106 and the drain electrode 108 are to be formed, openings corresponding to the respective electrode shapes are formed by dry etching or the like. Then, in these openings, for example, Al, Ti, and Au are deposited in this order, thus forming the source electrode 106 and the drain electrode 108.

Further, the mask on the AlGaN Schottky layer 104 is removed once, and a mask made of a SiO₂ film is formed on the AlGaN Schottky layer 104 again. Thereafter, in an area of the mask where the gate electrode 107 is to be formed, an opening corresponding to the gate electrode shape is formed by dry etching or the like. Then, in this opening, for example, Pt and Au are deposited in this order, thus forming the gate electrode 107.

The above process is a formation work for a front surface, i.e., a surface of the composite substrate 10 on which the nitride semiconductor layer 105 is formed. After the series of front surface formation work steps is completed, a work for a back surface, i.e., the opposite surface of the composite substrate 10 on the side where the Si-containing thermal-sprayed layer 2 is formed, is performed.

In step ST203, a part of the Si-containing thermal-sprayed layer 2 is subjected to a back surface grinding work, as necessary. This is because, in a case of further improving the heat dissipation property of the GaN-HEMT 300, thinning the Si-containing thermal-sprayed layer 2 is more advantageous for improving the heat dissipation property.

In step ST204, a back surface formation work step is performed as necessary. For example, in a case of desiring to provide a via-hole structure, the via-hole structure is formed through the back surface formation work step.

In a dicing step in step ST205, the wafer for which the front surface formation work and the back surface formation work have been completed is diced to be separated into individual GaN-HEMT elements.

Through the above steps, the GaN-HEMT 300 shown in the sectional view in FIG. 6 is completed.

In the structure of the GaN-HEMT 300 and the production method therefor according to embodiment 5, the Si-containing thermal-sprayed layer 2 remains, whereby there is such an advantage that the SiC substrate 1 can be extremely thinned as compared to the conventional case and thus even the SiC substrate 1 having a thickness of 0.1 mm or less for which handling is difficult can be produced by a general GaN-HEMT production process without the need of special features. That is, it becomes possible to obtain the GaN-HEMT 300 having a high heat dissipation property and a structure that contributes to reduction of production cost.

In the structure of the GaN-HEMT 300 according to embodiment 5, the Si-containing thermal-sprayed layer 2 needs to be electrically at a ground level. Therefore, as the material of the Si-containing thermal-sprayed layer 2, high-resistance Si or the like is not appropriate and low-resistance N-type Si not provided with delay characteristics is preferable.

### Embodiment 6

In a method for producing a GaN-HEMT 200 according to embodiment 6, as shown in a sectional view of the GaN-HEMT 200 in FIG. 5, the Si-containing thermal-sprayed layer 2 of the composite substrate 10 is completely removed unlike the structure of the GaN-HEMT 300 and the production method therefor according to embodiment 5.

After the GaN-HEMT front surface formation work in FIG. 12 is completed, the Si-containing thermal-sprayed layer 2 is removed through etching by nitric hydrofluoric acid.

In the GaN-HEMT production method using the conventional SiC substrate, a necessary thickness of the SiC substrate for the GaN-HEMT is 0.05 to 0.1 mm. Therefore, a part corresponding to about 0.4 mm, which is unnecessary in the SiC substrate, needs to be ground and removed using a diamond whetstone, thus causing a problem of increasing the GaN-HEMT production cost. In addition, in this case, the grinding is performed on one surface side, and therefore thickness variation management becomes severe, thus causing a problem of further increasing the production cost.

In the method for producing the GaN-HEMT 200 according to embodiment 6, a back surface grinding work using diamond and severe thickness management for the SiC substrate, which would be necessary in the conventional GaN-HEMT production method, are unnecessary, and thus the production cost can be reduced.

The Si-containing thermal-sprayed layer 2 may be ground and removed as in conventional art. Also in this case, an expensive tool such as a diamond whetstone which would be necessary in conventional art is unnecessary, thus providing an effect that a grinding work can be performed at a high speed using inexpensive whetstone/abrasive grains.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 SiC substrate

2 Si-containing thermal-sprayed layer

2a Si-containing thermal-sprayed layer after Si thermal spraying

10 composite substrate

30 cavity

35 dispersion material

40 impurities

45 SiOₓ intermediate layer

102 AlN buffer layer

103 GaN buffer layer

104 AlGaN Schottky layer

105 nitride semiconductor layer

106 source electrode

107 gate electrode

108 drain electrode

200, 300 GaN-HEMT

1. A composite substrate comprising:
a SiC substrate; and
a Si-containing thermal-sprayed layer which is provided at one surface of the SiC substrate so as to support the SiC substrate and is made of a material obtained by melting Si or a Si alloy, the Si-containing thermal-sprayed layer being doped with impurities.

2. The composite substrate according to claim 1, wherein
a thickness of the SiC substrate is 0.01 mm or more and 0.1 mm or less.

3. The composite substrate according to claim 1, wherein
a thickness of the Si-containing thermal-sprayed layer is 0.5 mm or more.

4. The composite substrate according to claim 1, wherein
the Si-containing thermal-sprayed layer contains a dispersion material made of ceramic.

5. The composite substrate according to claim 4, wherein
the ceramic is any one of AlN, BN, and C.

6. (canceled)

7. The composite substrate according to claim 1, wherein
a SiOₓ intermediate layer is provided between the SiC substrate and the Si-containing thermal-sprayed layer.

8. The composite substrate according to claim 1, wherein
a diameter of the SiC substrate is 4 inches.

9. A method for producing a composite substrate, comprising:
a bonding work step of bonding a SiC substrate to a plate-shaped member;
a thermal spraying step of spraying Si doped with impurities or a Si alloy doped with impurities, to one surface of the SiC substrate; and
a debonding step of debonding, from the plate-shaped member, the SiC substrate and a Si-containing thermal-sprayed layer doped with the impurities and formed at the one surface of the SiC substrate by the Si or the Si alloy being sprayed.

10. A semiconductor device comprising:
the composite substrate according to claim 1;
a nitride semiconductor layer formed on a side of the composite substrate where the SiC substrate is present;
a source electrode and a drain electrode formed on the nitride semiconductor layer; and
a gate electrode formed between the source electrode and the drain electrode.

11. A method for producing a semiconductor device, comprising:
a crystal growth step of forming a nitride semiconductor layer through epitaxial growth on the composite substrate according to claim 1; and
an electrode formation step of forming a source electrode, a drain electrode, and a gate electrode on the nitride semiconductor layer.

12. The method for producing the semiconductor device according to claim 11, further comprising a step of removing the Si-containing thermal-sprayed layer, doped with the impurities, of the composite substrate.
